(19) United States
(12) Patent Application Publication
(10) Pub. No.: US 2018/0213669 A1
(43) Pub. Date: Jul. 26, 2018

(54) MICRO DATA CENTER (MDC) IN A BOX SYSTEM AND METHOD THEREOF

(71) Applicant: Prasad Lalathuputhanpura KOCHUKUNJU, Bangalore (IN)

(72) Inventor: Prasad Lalathuputhanpura KOCHUKUNJU, Bangalore (IN)

(21) Appl. No.: 15/743,447

(22) PCT Filed: Jul. 11, 2016
(86) PCT No.: PCT/IN2016/000183

§ 371 Date: Jan. 10, 2018

(30) Foreign Application Priority Data
Jul. 10, 2015 (IN) 3530/CHE/2015

(51) Int. Cl. H05K 7/14; G06F 1/18; G06F 1/32; G06F 9/455

(52) U.S. Cl. CPC H05K 7/1488; H05K 7/1487; G06F 2009/45579; G06F 1/32; G06F 9/45558; G06F 1/18

(57) ABSTRACT

The various embodiments of the present invention disclose a Micro Data Center (MDC) system, wherein the system comprising a rack mountable box (100) housing, one or more uplink interfaces (102), one or more management interfaces (104), one or more switch cards (106), one or more line cards (108), one or more server cards (110), a power supply module (112), one or more visual indicators (114), a storage tray (116), and one or more Input-Output (I/O) cards (118), wherein the MDC system is a reconfigurable data center in a box model, where the one or more components of the MDC system are interoperably connected through on a peripheral component interconnect express (PCIe) Express MDC Super compute Fabric.

### TECHNICAL FIELD

The present invention relates to the field of computing and storage systems and particularly relates to a system for providing a high speedmicro data center as a box model and a method thereof.

### BACKGROUND ART

In current-generation computers, the central processing unit (CPU) is connected to the system memory and to peripheral devices by a shared parallel bus, such as the Peripheral Component Interface (PCI) bus or the Industry Standard Architecture (ISA) bus. Essentially, a bus is the channel or path between components in a computer. Likewise, current server-to-server connections and links to other server-related systems, such as remote storage and networking devices, depends on parallel bus technology. Server design dependent on a shared bus input/output (I/O) architecture may deliver for example 512 megabytes per second (MB/sec) of potential bandwidth that is shared among devices connected to the bus.

As data path-widths grow, and clock speeds become faster, the shared parallel bus becomes too costly and complex to keep up with system demands. In response, the computer industry is working to develop next-generation bus standards. Thus, data centers came into existence to solve the problems of keeping up with complex system demands. The data center is a facility used to house computer systems and associated components, such as telecommunications and storage systems. The data center generally includes redundant or backup power supplies, redundant data communications connections, environmental controls (e.g., air conditioning, fire suppression) and various security devices. Large data centers are industrial scale operations and can consume as much electricity as a small town. The set up for installing a data center for any particular organization can cost a lot of money depending on the requirements and additional accessories.

Further, micro data center (MDC) came into existence as an alternative for the data center, wherein the micro data center is a system with portable data center capacity. Modern Hyper Dense and low power data centers use Data Center in a Box (DCIB) concept rather than traditional 1 rack unit (1U) server blades. Traditionally, a data center rack consists of 42 self-contained 1U racks, wherein each has its own CPU, memory, disk, and network devices tightly integrated in a server board.

Data Center technology is moving towards disaggregated architecture. The disaggregated architecture contains CPU and Memory pools, a disk pool, network interface (NIC) pool which is connected by a high bandwidth and low latency networks. A major deployment advantage of the disaggregated Data Center in a Box architecture is that it allows different system components, i.e. CPU, memory, disk, and NIC, to be upgraded independently and disaggregation decouples each host (CPU/memory module) from I/O devices such as disk controllers and network interfaces, and enables sharing of I/O resources.

A major application of such a disaggregated architecture is to serve as a converged solution of server, storage and network, and acceleration/offloading. Data Center in a Box (DCIB) offers a new way to deploy network services such as, but not limited to, firewall, intrusion detection, proxy, network address translation (NAT), and acceleration offload functions such as TCP/IP, UDP, iSCSI, FCoE, IPSec, SSL, TLS 1.2, DTLS, ECC Suite B, and encryption algorithms such as, but not limited to, DES, 3DES, ARC4, AES 256-bit (ECB, CBC, XCBC, CNTR, GCM), MD5, SHA-1, SHA-2, MAC-MD5/SHA-1/SHA-2, HMAC-MD5/SHA-1/SHA-2 (including SHA-224, SHA-256, SHA-384, SHA-512), RSA 2049, RSA 4096, Diffe Hellman etc, for a disaggregated architecture. To guarantee performance, DCIB utilizes several hardware virtualization technologies to accelerate the processing speed of various network functions in a virtualized environment in data plane.

An efficient disaggregated DCIB requires several key factors. First, for decoupling each system component into CPU/memory pool, disk pool, and NIC pool, a high speed and low latency network is required to interconnect each pool. Second, CPU is decoupled from the I/O device module and Co-processor COTS module. In other word, the interconnecting network should have the capability for sharing the I/O devices and Co-processors among multiple hosts efficiently. Third, to guarantee application-level network service performance in a DCIB environment, hypervisor should allow direct access from the guest OS to the assigned I/O devices, avoiding the context switching overhead and delivering the native performance. Fourth, the interconnecting network should support high availability in terms of control plane failure and data plane failure. And fifth, the proposed solution should be compatible with existing COTS I/O solutions in such a way that avoids the vendor lock-in situation by depending on any proprietary solution.

Currently data fabric switching is done using Ethernet, Fiber Channel and Infini-band. Ethernet has got very high latency and thus is not suitable for High Performance Computing (HPC) environments. Though Infini-band is often used as a server connects in HPC systems, the cost of the Infini-band system and peripherals is relatively higher. Also the Commercial off-the-shelf (COTS) hardware cannot be directly interfaced with the Infini-band COTS solutions.

In view of the foregoing, there is a need for providing system for enabling high speed data center and method thereof that can provide high speed data storage and data access to user.

The above mentioned shortcomings, disadvantages and problems are addressed herein and which will be understood by reading and studying the following specification.

### SUMMARY OF THE INVENTION

The various embodiments of the present invention disclose a high speed Micro Data Center (MDC) system in a box model and a method of working thereof. The micro MDC can solve the problems existing in the current architecture of the data center in a box (DCIB) by aggregating a server, storage and network, and acceleration/offloading modules in the single system, which can be communicated with each other easily, and thereby enhancing the data processing and storing processes faster and efficiently.

According to an embodiment herein, the Micro-data center (MDC) is a smaller, containerized (modular) data center system that is designed to solve different sets of problems or to take on different types of workload that cannot be handled standalone by traditional facilities or even large modular data centers.

According to an embodiment herein, Micro servers are low power and low cost devices which does not have computing power to handle high computing workloads. MDC accelerate micro servers using virtualized acceleration offload modules to handle different type of workload which is handled by traditional and high end computing processors.

According to an embodiment herein, MDC works on an “MDC Supper Compute Fabric” which is a PCIe fabric switch having 9.6 Terabits switch capacity and 140 ns latency between its switch ports. Further MDC implements a concept of “Acceleration Virtualization” using the MDC supper compute fabric and built-in low latency high speed interconnects.

According to an embodiment of the present invention, the micro data center (MDC) is a DCIB works on a “MDC Super Compute Fabric” which has disaggregated architecture. By having PCI Express as the main fabric interconnect, all the components can interoperate directly with one another. By removing the need to translate from PCI Express (on the component) to Ethernet, the cost and power of the DCIB can be substantially reduced. Communicating directly between components also reduces the latency. The PCIe fabric has the ability to handle different data types at a line speed with a single fabric based on PCI Express. This eliminates the need to partition different types of data using different protocols, allowing a truly converged fabric where processors and endpoints can be allocated across the rack, as needed. And, the processors and endpoints all communicate efficiently across the low-latency, high-bandwidth PCI Express path.

In an embodiment of the present invention, the MDC is adapted to interface various PCIe based I/O cards and co-processors cards as PCIe has become nearly a universal interface for peripheral devices, e.g., storage, network, and graphical devices. Connecting these devices using PCIe fabric interface and PCIe fabric network eliminates the burden of layering PCIe devices on top of another protocol. In another embodiment of the present invention, the PCIe fabric allows multiple guest operating systems running simultaneously within a single host processor or multiple host processors to natively share PCIe devices using the PCIe Single-Root I/O Virtualization (SR-IOV) capability. With the hypervisor support, guest operating system could directly access the I/O devices without the over-head of hypervisor involvement. With the ability to share SR-IOV based cards with multiple host processors or VMs working one processor or multiple processors without any OS software modification. It is a pseudo implementation of multi Root I/O Virtualization (MRIOV) feature in case of multiple processors and VMs in multiple processors. Acceleration offload, encryption offload, other network and storage offload mechanism are implemented in MDC using SRIOV feature. Traditional Ethernet will not able to achieve the PCIe performance and low latency.

In another embodiment of the present invention, the MDC can share HDD/SSD pool or NVME storage cards for multiple processors or VMs running in one processor or multiple processors. In another embodiment of the present invention, the MDC comprises of multiple midplanes and a narrow backplane to improve the thermal performance and reduce the cost and complexity of the DCIB system.

In another embodiment of the present invention, the MDC is adapted to map the entire memory address space of one or more hosts connected to a PEX9797 based switch card into a global memory address space, and then making the remote memory access traditionally required special adapters to become as simple as a local memory access in an efficient and secure way. The mapping helps the system to implement peer-to-peer memory DMA transfers from endpoint devices. Peer-to-Peer implementation will save the computing power of host processors by introducing zero copy DMA transfers.

In another embodiment of the present invention, the MDC provides data path redundancy on PCIe links.

In another embodiment of the present invention, the MDC comprises of PCIe based DCIB system that connects together multiple servers, storage bays and acceleration offload PCIe based modules using the MDC Super Compute Fabric with a global memory address space shared across a plurality of servers. The MDC can provide a hardware-based remote DMA mechanism (TWC) that allows one host processor to initiate a DMA transaction against another processor's memory in the same and remote MDC and supports socket-based communications for legacy network applications and host to host zero memory copying for applications designed specifically to take full advantage of MDC.

In another embodiment of the present invention, MDC implements a Software Defined Data Centre (SDDC). Software Defined Data Centre integrates the software-definability of various data-centre resources and services. In a SDDC, all elements of infrastructure—power, compute, memory, storage, networking, acceleration and security are virtualized and delivered as a service.

The foregoing has outlined, in general, the various aspects of the invention and is to serve as an aid to better understand the more complete detailed description which is to follow. In reference to such, there is to be a clear understanding that the present invention is not limited to the method or application of use described and illustrated herein. It is intended that any other advantages and objects of the present invention that become apparent or obvious from the detailed description or illustrations contained herein are within the scope of the present invention.

### DESCRIPTION OF THE DRAWINGS

The other objects, features and advantages will occur to those skilled in the art from the following description of the preferred embodiment and the accompanying drawings in which:

FIG. 1a is a block diagram illustrating components of a Micro Data Center (MDC) system, according to an embodiment of the present invention.

FIG. 1b is a schematic block diagram illustrating architecture of a Micro Data Center (MDC) system, according to an embodiment of the present invention.

FIG. 2 is a schematic block diagram illustrating aside view of the micro data center (MDC), according to an embodiment of the present invention.

FIG. 3 is a schematic diagram illustrating data path connections of the different switch card interfaces with each other, according to an embodiment of the present invention.

FIG. 4 is a schematic diagram illustrating providing power supply to the MDC, according to an embodiment of the present invention.

FIG. 5 is a schematic architecture illustrating distribution of server card of the MDC, according to an embodiment of the present invention.

FIG. 6 is a schematic diagram illustrating architecture of a server card of the MDC, according to an embodiment of the present invention.

FIG. 7 is a schematic diagram illustrating architecture of the switch card connection with the other modules in the MDC, according to an embodiment of the present invention.

FIG. 8 is a schematic diagram illustrating one of the MDC switch card data path, according to an embodiment of the present invention.

FIG. 9 is a schematic diagram illustrating MDC system control path, according to an embodiment of the present invention.

FIG. 10 is a schematic diagram illustrating structure of an external enclosure of the MDC, according to an embodiment of the present invention.

FIG. 11 is a mechanical diagram illustrating a front panel of the MDC, according to an embodiment of the present invention.

FIG. 12 is a mechanical diagram illustrating a rear section of the MDC, according to an embodiment of the present invention.

FIG. 13 is a mechanical diagram, illustrating a cross section along the axis of mid-plane of the MDC, according to an embodiment of the present invention.

FIG. 14 is a block diagram illustrating functional components of an MDC system, according to an embodiment of the present invention.

FIG. 15 is a block diagram illustrating the functional components of a switch card of the MDC system, according to an embodiment of the present invention.

Although specific features of the present invention are shown in some drawings and not in others, this is done for convenience only as each feature may be combined with any or all of the other features in accordance with the present invention.

### DETAILED DESCRIPTION OF THE INVENTION

The various embodiments of the present invention disclose a high speed Micro data center (MDC) in a box system and method thereof. In the following detailed description of the embodiments of the invention, reference is made to the accompanying drawings that form a part hereof, and in which are shown by way of illustration specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined only by the appended claims.

The specification may refer to “an”, “one” or “some” embodiment(s) in several locations. This does not necessarily imply that each such reference is to the same embodiment(s), or that the feature only applies to a single embodiment. Single features of different embodiments may also be combined to provide other embodiments.

As used herein, the singular forms “a”, “an” and “the” are intended to include the plural forms as well, unless expressly stated otherwise. It will be further understood that the terms “includes”, “comprises”, “including” and/or “comprising” when used in this specification, specify the presence of stated features, integers, steps, operations, elements and/or components, but do not preclude the presence or addition of one or more other features, integers, steps, operations, elements, components, and/or groups thereof. As used herein, the term “and/or” includes any and all combinations and arrangements of one or more of the associated listed items.

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The Micro data center (MDC) according to the present invention is adapted for aggregating server, storage and network, and acceleration/offloading modules in the single system, which can be communicated with each other easily, and thereby enhancing the data processing and storing processes faster and efficiently.

According to an embodiment of the present invention, the micro data center (MDC) is a DCIB which works on a “MDC Super Compute Fabric” which has disaggregated architecture. MDC is a 10U hardware box with 9.6 Terabits of switching capacity. MDC is adapted to accommodate 72 Intel Xeon-D processors and 288 TB hard disk storage in server only mode. MDC in storage only mode can support up to 768 TB of hard disk storage. MDC has two switch cards and the switch cards can be configured in redundant and aggregation mode. In redundancy mode, it has support of maximum of 480 Gbps uplink and aggregation mode, it can have support of 960 Gbps uplink. The PCIe fabric PXE9797 can be chosen from Avago Technology or any other similar or higher version of the PCIe fabric for MDC switch and the fabric is designed to replace the “bridging” devices that operate within MDC.

This is possible because virtually all the components that form the foundation of the data center CPUs, storage devices, and communication devices have PCI Express as at least one of their connections. By having PCI Express as the main fabric, all the components can interoperate directly with one another. By removing the need to translate from PCIe (on the component) to Ethernet, the cost and power of the DCIB can be substantially reduced. Communicating directly between components also reduces the latency. It is common within data centers to have multiple fabrics within the rack and Ethernet is typically used for communications, and Fiber Channel is popular for storage. PCIe fabric has the ability to handle all the different data types at line speed with a single fabric based on PCI Ex-press. This eliminates the need to partition different types of data using different protocols, allowing a truly converged fabric where processors and endpoints can be allocated across the rack, as needed. And, the processors and endpoints all communicate efficiently across the low-latency, high-bandwidth PCI Express path.

MDC can interface various PCIe based I/O cards and co-processors cards as PCIe has become nearly a universal interface for peripheral devices, e.g., storage, network, and graphical devices, connecting these devices using PCIe fabric interface and PCIe fabric network eliminates the burden of layering PCIe devices on top of another protocol. In addition, PCIe fabric allows multiple guest operating systems running simultaneously within a single host processor or multiple host processors to natively share PCIe devices using the PCIe Single-Root I/O Virtualization (SR-IOV) capability. With the hypervisor support, guest operating system could directly access the I/O devices without the overhead of hypervisor involvement. MDC has stacking support and maximum of 10 MDC can be stacked up to scale up compute nodes and storage nodes without scarifying the latency in the network.

MDC is hardware solution with integrated software drivers. It is a 10U system and it is rack mountable. It has 36 server or 36 storage blades and supports any card in any slot philosophy. Each sever blade is populated with 2 Xeon-D or other compute processors. Each Storage card has maximum of 6, 2.5″ hard drives it can either SATA disk or SAS disks. MDC also supports HDD and SSD hard drives. It has 9.6 Tera-bits of PCIe backplane capacity and through this backplane MDC interconnects all processors, storage disks, co-processors and IO devices. MDC software uses 10U hardware platform and PCIe fabric architecture features. PCIe fabric allows host machines to access all resources including other host memory as memory read and writes operations. The MDC creates a PCIe global memory space which can be accessed by all host processor in the MDC and other networked MDC. The MDC proposes an I/O resource sharing mechanism which hosts processors can share a NIC card network bandwidth; acceleration and offload capability thereby factorize the NIC hardware cost among each pool of hosts. Every configuration access, data transfer between host memory and device and DMA transfers is a memory read or writes operation. The PCIe fabric-based MDC allows multiple Hosts to share data with endpoints using standard Single Root-I/O Virtualization-capable (SR-IOV-capable) devices. An SR-IOV device usually allows multiple virtual machines (VMs) within a single Host to share an endpoint. The PCIe fabric extends that to allow the VMs within multiple Hosts to have that same capability. This feature operates with the standard, vendor-supplied SR-IOV drivers so that the existing hardware-installed and software-installed base is maintained.

The MDC has 768 TB of Serial Attached SCSI/Serial AT Attachment (SAS/SATA) Hard disc Drive (HDD) or Solid State Drive (SSD) support in storage only configuration. MDC can also support PCIe based high speed storage. MDC has 36 slots for storage cards and each of the cards can house 6 SAS/SATA HDD or SSD. In mixed mode configuration, it can accommodate in each slot a server cards or a storage card. MDC has both storage cards and server cards capability; each host processor can access the storage pool of the system. MDC has ability to share storage pool with multiple host processors and VMs which is running in one host processor or multiple processors.

MDC Super Compute Fabric enables those applications within a data center which uses Ethernet as a fabricto run, unchanged, through the use of a virtual Ethernet Network Interface Controller (NIC) on each Host Port. The MDCPCIe fabric solution is built on a hybrid hardware/software platform. The Data path have direct hardware support, enabling the fabric to offer non-blocking, line-speed performance with features such as I/O sharing and Ethernet Tunneling DMA. MDC switch card has management processor (MCPU) to setup and control. MCPU has the capability to initialize the fabric, configure the routing tables, handle serious errors, Hot Plug events, and enable MDC to extend the capabilities without upgrading the hardware. MDC support software defined architecture and with help of MCPU it enables the ability to allow multiple hosts to reside on the PCI Express network using standard Host-enumeration methods. The MDC archive these features by synthesizing a PCIe hierarchy for each Host and the Hosts “see” a typical PCI Express hierarchy; however, the Hosts only see what the MCPU allows them to see. The Hosts have no direct connection with data path of the fabric, and are thus able to run standard enumeration and related applications.

MDC support card hot plug features to allow on the field replacement of server blades, storage tray and switch cards in the system. MDC has six switch cards and each switch card has 8×8 PCIeExpressFabric interconnected in flat mesh topology to achieve full throughput connectivity. Commercially available PCIeExpressFabric does not fully support hot plugging of endpoints and host nodes, but MDC management software implemented a comprehensive hot plug mechanism by using serial hot plug feature of PEX9797.

MDC is a8 KW DCIB system and each server blades dissipate around 150 W and switch card dissipates 300 W of power. There are 36 server cards and 6 switch cards are available in the system. System mechanical, midplane and backplane are designed in a unique way to allow maximum thermal performance. MDC has four midplanes and one backplane and all switch cards are connected to one another over MDC backplane overmesh topology. There is a lots of air ventilation between these four midplanes and one backplane and it helps the system to transfer large amount heat from hot zone to heat ex-changer fans. The major benefit for this midplane—backplane design is it has the flexibility of slotted midplane with lower area and the cost. Realization of the system using multiple mid-planes is one of the unique features of MDC. 12 server cards are connected to one switch card and to reduce the length of high speed differential, lines, these server connections are directly mated with switch card connectors. Even though the connections pass through the mid-plane cross section, it is not routed through mid-plane.

In addition, MDC takes advantage of the global memory address space to build its inter-host communication mechanism, based on PXE9797's Tunneled Window Connection (TWC) mechanism (hardware-based remote direct memory access), which serves as the fundamental communication primitive in MDC. TWC allows one host processor to initiate a Direct Memory Access (DMA) transaction against another host processors' memory in the same MDC or another networked MDC without any software intervention. Compared with existing RDMA mechanism provided by InfiniBand, MDC's TWC is direct and native, in which it does not require additional adapter in the data path to store into the internal device memory and encapsulate/decapsulate payload into another protocol, e.g., InfiniBand protocol. As a result, the data transfer between two ends is in a cut-through fashion instead of store-and-forward.

MDC's I/O sharing mechanism allows VM running on distinct servers to access the shared I/O devices directly without hypervisor's involvement. With various hardware I/O device virtualizations, MDC can achieves higher performance for guest OS with minimal virtualization overhead. MDC can utilize optimized KVM hypervisor to reduce the interrupt overhead associated with hypervisor.

In ExpressFabric Mode, PCIe will have only one root complex (MCPU) and it will manage all the end-points enumeration and once enumeration is complete, it will assign end points to each host CPU/VMs.

When MCPU become one point failure of the system, it will result in MDC's control plane and root complex failure. MDC has a standby MCPU processor it will take over the control plane functions to avoid service disruption. One of the unique features of MDC is the data plane redundancyin PCIeExpressFabric and there is no support for data plane redundancy mode in PEX9797 PCIe Express Fabric switch. MDC implements data plane redundancy using active and standby PCIe based switch cards. Both active switch card and standby switch card will sync in real time over Ethernet connection between them, when active switch card fails, standby card detect the failure and redundant MCPU processor on standby card has global memory map and enumeration details of the system, it will redirect the data path through standby switch card and later standby switch card will act as active switch card. All the host processors are connected to both active and redundant switch card, so data path from host to new active card can be enabled and hosts will not be affected by the switchover action. MDC has a backplane and it connects all six switch card over PCIe interfaces. A switch card has a flat tree topology of 2PEX9797 PCIeExpressFabric switches. Since it is a flat tree topology, failure of one PEX9797 will not affect all the hosts in the system, it will affect only those host processors that are connected to the failed PEX9797. There will be alternate mesh paths available to other host processors and MDC will work without much service disruption.

In an embodiment of the present invention, the MDC comprises of six switch cards with total 72×4 PCIe Gen3 ports and software can configure these switch ports into different functions based on required server and storage capacity. In MDC, switch Ports are classified into four types, each with an attribute:

1. Downstream Portto which an endpoint device (I/O card, NIC, Storage etc) is attached.
2. Fabric Port that connects to another switch within the fabric
3. Management Port that Connects to the MDC MCPU
4. Host port at which a Host processor/VM can be attached.

According to the present invention, the MDC uses PEX9797 PCIe switch from Avago to implement MDC Super Compute Fabric. PEX9797 ExpressFabric provides three separate Host-to-Host communications mechanisms that can be used alone or in combination. The MDC uses all these mechanisms to integrate different types of endpoints, hosts and PEX9797.

1. Tunneled Windows Connection (TWC) mechanism—Allows Hosts to expose windows into their memories for access by other Hosts and then allows ID-routing of Load/Store Requests to implement transfers within these windows, all within a connection-oriented transfer model with security.

2. Integrated DMA Controllers—Supports a Network Interface Controller (NIC) Descriptor for Ethernet tunneling using the TCP/IP stack.

3. ID Routing—ID-routed PCI Express Vendor-Defined Messages and an ID-Routing prefix, used in front of otherwise address-routed Transaction Layer Packets (TLPs), are used together with routing mechanisms that allow non-blocking Fat Tree (and diverse other topology) fabrics to be created that contain multiple PCI Express Bus Number spaces.

The DMA messaging engines built into ExpressFabric switches expose multiple DMA virtual functions (VFs) within each PEX9797 for use by virtual machines (VMs) running on MDC, internally these are connected to MDC switch. Each DMA VF emulates a NIC embedded within the PEX9797. Servers can be directly connected to the fabric; no additional silicon for NICs or Host Bus Adapters (HBAs) is required. The embedded NICs eliminate the latency and power consumption of external NICs and Host Channel Adapters (HCAs) and have numerous latency and performance optimizations. MDC ExpressFabric also supports sharing Single Root-I/O Virtualization (SR-IOV) endpoints, as well as multifunction endpoints across multiple Hosts. MDC allows the sharing of an expensive acceleration IO cards, FPGA cards, DSP cards, Solid-State Drive (SSD) controller etc by multiple servers for extending communications reach beyond the ExpressFabric boundaries using shared Ethernet NICs or converged net-work adapters. Using a management processor (MCPU), the VFs of multiple SR-IOV endpoints can be shared among multiple servers without need for any server or driver software modifications. Single function endpoints connected to the fabric may be assigned to a single server using the same mechanisms.

Further, the MDC Super Compute Fabric can support the MR sharing of multifunction endpoints, including SR-IOV end-points. This feature is referred to as Express-IOV. The same mechanisms that support ExpressIOV also allow a conventional, single function endpoint to be located in global space and assigned to any MDC Host in the same Bus Number Domain of the fabric. Shared I/O of this type can be used in ExpressFabric clusters to make expensive storage endpoints (such as SSDs) available to multiple servers and for shared network adapters to provide access into the general Ethernet and broadband cloud. The endpoints shared or otherwise, are located in Global Space, on the fabric side of the TWCs that isolate each Host Port. The PFs in these endpoints are managed by the vendor's PF driver running on the MDC MCPU, which is at the Upstream/Management Port of its BUS Number Domain in the Global Space Fabric. Translations are required to map transactions between the local and global spaces. The PEX9797 implements a TLP Redirection mechanism to make those translations transparent to the software running on the attached Hosts/servers. TLP redirection allows the MDC MCPU to snoop on Configuration Requests and when necessary, intervene on them to implement sharing. This snooping and intervention is transparent to the Hosts, except for a small incremental delay. The MDC MCPU synthesizes Completions during Host enumeration to cause each Host to discover its assigned endpoints at the Downstream Ports of a standard, but synthetic, PCI Express Fanout switch. Thus, the programming model presented to the MDC host for I/O is the same as that host would see in a standard single Host application with a simple Fanout switch.

Through TLP redirection, the MDC MCPU is able to configure ID routed tunnels between each Host and the endpoint functions assigned to it in the switch without the knowledge or cooperation of the Hosts. The Hosts are then able to run the vendor supplied drivers without change.

Memory-Mapped I/O (MMIO) requests the ingress at a MDC Host Port is tunneled downstream to an MDC endpoint by means of an address trap. For each Base Address Register (BAR) of each I/O function assigned to a Host, there is a Content-Addressable Memory (CAM) entry (address trap) that recognizes the Host Domain address of the BAR and supplies both a translation to the equivalent Global Space address and a destination BUS Number for use in a Routing Prefix added to the Transaction Layer Packet (TLP).

Further, Request TLPs are tunneled upstream from a MDC endpoint to a Host by Requester ID. For each I/O function Requester ID (RID), there is an ID trap CAM entry (Inside PEX9797) into which the function's Requester ID is associated to obtain the Global BUS Number at which the Host to which it has been assigned is located. This BUS Number is again used as the Destination BUS in a Routing Prefix. Because Memory Requests are routed upstream by ID, the addresses that they contain remain in the Host's Domains; no address translations are needed. Some Message Requests initiated by MDC endpoints are relayed through the MCPU to allow it to implement the message features independently for each Host's virtual hierarchy.

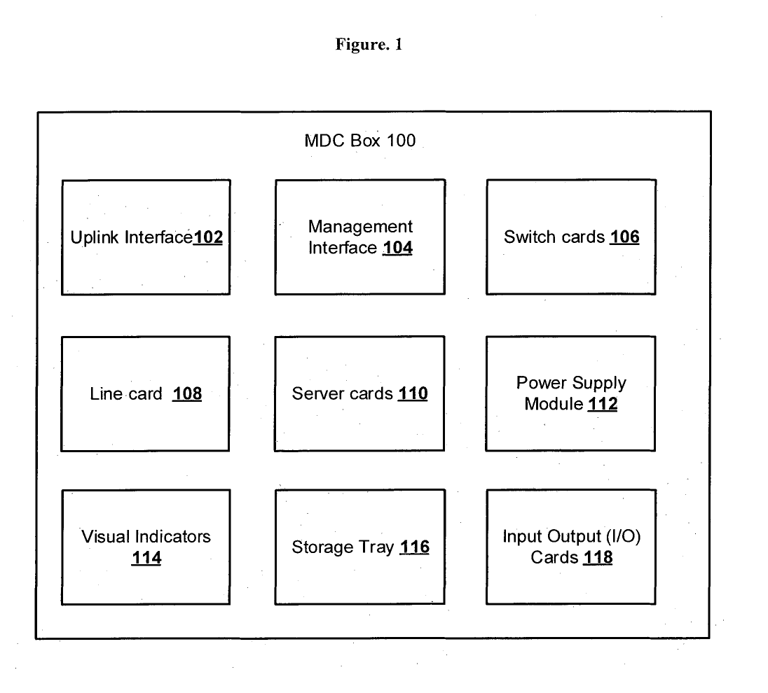

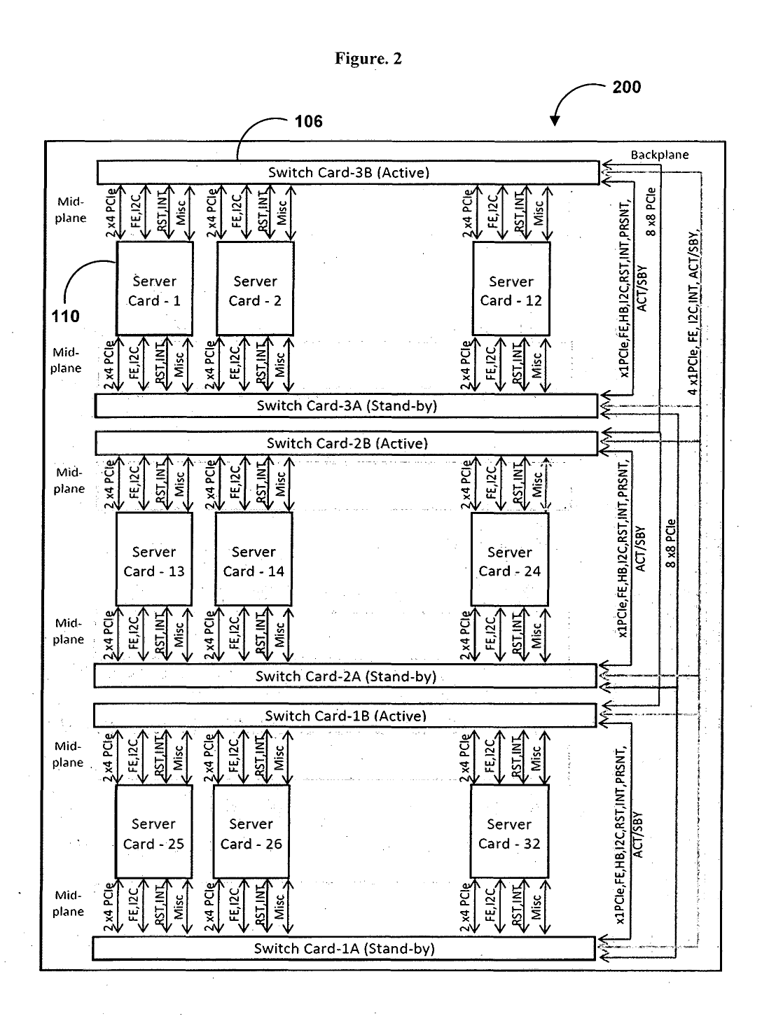

FIG. 1a is a block diagram illustrating components of a Micro Data Center (MDC) system, according to an embodiment of the present invention. In an embodiment of the present invention, the MDC system comprises of a rack mountable box (100) housing, one or more uplink interfaces (102), one or more management interfaces (104), one or more switch cards (106), one or more line cards (108), one or more server cards (110), a power supply module (112), one or more visual indicators (114), a storage tray (116), and one or more Input-Output (I/O) cards (118), wherein the MDC system is a reconfigurable data center in a box model, where the one or more components of the MDC system are interoperably connected through on a peripheral component interconnect express (PCIe) Express MDC Super compute Fabric. The FIG. 1b is a schematic block diagram illustrating architecture of a micro data center (MDC) system, according to an embodiment of the present invention. The MDC 100 is a converged solution of micro servers, storage, acceleration/offload modules and networks. There are options for 36 server cards 102 and 6 switch cards 104 in server only configuration. In storage only solution, it can have house up to 36 storage cards and each card can accommodate 6 HDD/SSD drives. Further, in both modes, there are options for 2 IO cards house in each switch cards, and each IO card can house up to 4 PCIe Gen3 NICs or data path acceleration modules such as TCP/IP, UDP, iSCSI, FCoE, IPSec, SSL, TLS etc.

In an embodiment of the present invention, the MDC system comprises of external interfaces such as, but not limited to, uplink interfaces, management interfaces, power supply, visual indicators, backplane interfaces, server card, storage tray, switch card, IO card, and the like.

The uplink interfaces comprises of 12×8 PCIe uplink ports, support for custom or standard low profile half-length PCIe cards, support for 40G or 10G or Gigabit Ethernet NICs, and can support combination of 40G, 10G and Gigabit Ethernet NICs. In redundancy mode, 4 I/O PCIe slots can be active and remaining 4 I/O PCIe slots can be placed on stand-by mode. The Uplink interfaces are accessible from rear side of the chassis.

The management interfaces on each switch card can be of the type 4×GbE electrical ports over RJ-45 connector. In redundancy mode, two ports can be active and others can be placed on stand-by mode. The management interfaces are accessible only from rear side of the chassis. The power supply input to the MDC can be in the range of 100V to 240 VAC current, and the MDC can consume 8000 W power in fully loaded system. The power supply works on 7×1200 W power supply module in 6+1 mode.

The visual indicators of the MDC system comprises of, but not limited to, one tri color LED on each card to indicate the power status, LEDs on each card front panel to indicate KVM status, Ethernet link and activity, LED panel containing one LED per slot to indicate the configuration status of the slot, and the like. The backplane interface can be the PCIe backplane, wherein the PCIe backplane can be interconnected with the cards in the MDC1000 chassis.

The server card of the MDC comprises of, but not limited to, 2×x4 PCIe interfaces to each Switch card−total 4×x4 PCIe, 1×FE interface to each Switch card−total 2×FE, 2×I2C interface to each Switch card−total 4×I2C interface, 1×reset input from each Switch cards, 1×input line from each Switch card to select the processor to be reset−used with reset input, 1×input line from each Switch card to select board reset or processor reset—used with reset input, 1×interrupt output to each Switch card, 1×input line from each Switch cards to indicate each Switch card status (Active or Stand-by), 1×output line to switch cards to indicate card presence status, 2×GPIO signals to Switch cards, 7×geographical address input lines, 12V main power from backplane to Server card, and the like.

The storage tray of the MDC comprises of, but not limited to, 1×8 PCIe interfaces to each Switch card−total 2×x8 PCIe, 1×FE interface to each Switch card−total 2×FE, 2×I2C interface to each Switch card−total 4×I2C interface, 1×reset input from Switch cards, 1×interrupt output to Switch cards, 2×input line from Switch cards to indicate Switch card status (Active or Stand-by), 1×output line to switch cards to indicate card presence status, 2×GPIO signals to Switch cards, 7×geographical address input lines, 12V main power from backplane to Server card, and the like.

The switch card of the MDC comprises of, but not limited to, 2×x4 PCIe interfaces to each Server slot−total 72×x4 PCIe, 2×x8 PCIe to IO card, 2×PCIe reference clock to IO card, 1×Fast Ethernet (FE) interface to each Server slot−total 36×FE, 1×FE interface to second Switch card, 2×FE uplink port to IO card, 6×I2C interface from MCPU to Server slots for IPMC support, 1×Reset output to each Server slot−total 36 reset outputs, 1×output line per 12 Server slots to select the processor to be reset−total 12 lines, 1×output lines per 12 Server slots to select board reset or processor reset−total 12 lines, 1×Interrupt input lines per 12 Server slots−total 12 lines, 1×card presence input line from each Server slot−total 36 lines, 2×card presence input lines from IO card, 2×GPIO signals to each Server slot−total 72 lines, 1×input and 0.1×output heart beat signal to second Switch card−total 2 lines, 7×geographical address input lines, 12V main power from mid-plane to Switch card, and the like.

The IO card of the MDC comprises of, but not limited to, 2×x8 PCIe interfaces to Switch card−One×8 PCIe from each PCIe slot in the IO card, 1×PCIe reference clock from Switch card−One clock to each PCIe slot in the IO card, 1×I2C interface to Switch card−One I2C to each PCIe slot in the IO card, 12V main power and 3.3V stand-by power from respective switch card to the server card, and the like.

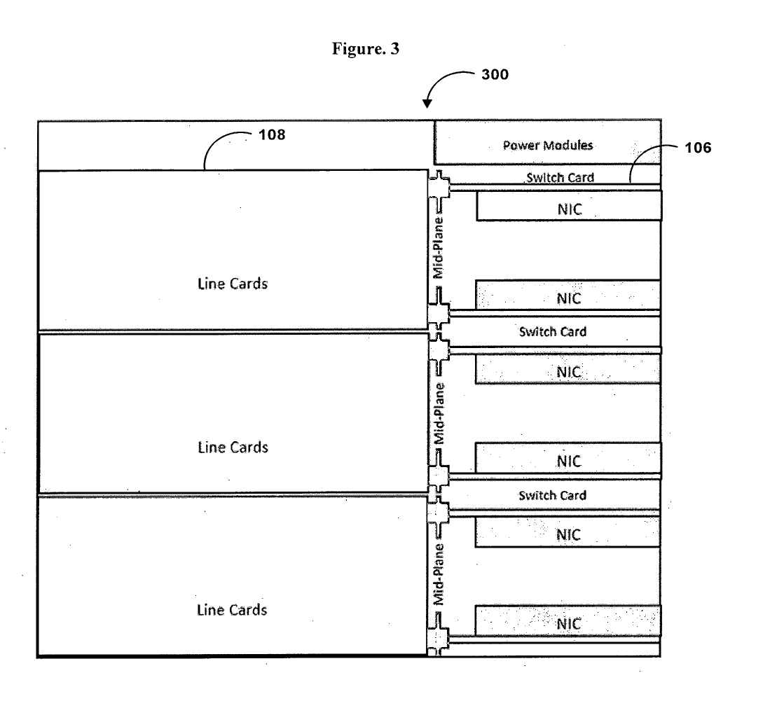

FIG. 2 is a schematic diagram illustrating side view of the micro data center (MDC), according to an embodiment of the present invention. The MDC uses split mid-plane and a backplane topology, wherein the gap between mid-plane cards may use slots for air flow. MDC backplane connects all switch cards, which is mounted vertically to mid-plane and switch cards. MDC has total four mid-planes of three types in the system. First type has the size of 1.9″×17″ and second type has a size of 3.3″×17″ and third type has a size of 1.65″×17″. There are 3 air vents of the size 2.5″×17″ and approximately 40% of the back side of the system has provision for air circulation. The arrangement of gaps, slits and air vents have improved the thermal performance of system 2.5-3 times the normal backplane architecture followed in traditional designs which has normally 17% of air circulation in the backplane. The architecture of the mid-plane and backplane reduces the backplane PCB cost as well as it improves the air circulation inside the MDC system. For high speed equipment's which carry more that 10 GHz in a differential pair prone for signal losses. In an embodiment of the present invention, the MDC backplane PCB can be made up of the materials such as, but not limited to, N4000-13 EP SI, Megtron-6, and the like, the backplane suits and helps the PCB to carry signals with a speed of 10 GHz or above without affecting signal quality. Each high speed differential pairs are equalized and amplified using PCIe Gen3 rrtimers to accommodate the signal loss. MDC system methods detect the slot number and location of the Re-timer and re-program EEPROM of PCIe retimer to accommodate trace length correction in the event of hot insertion of cards into the system.

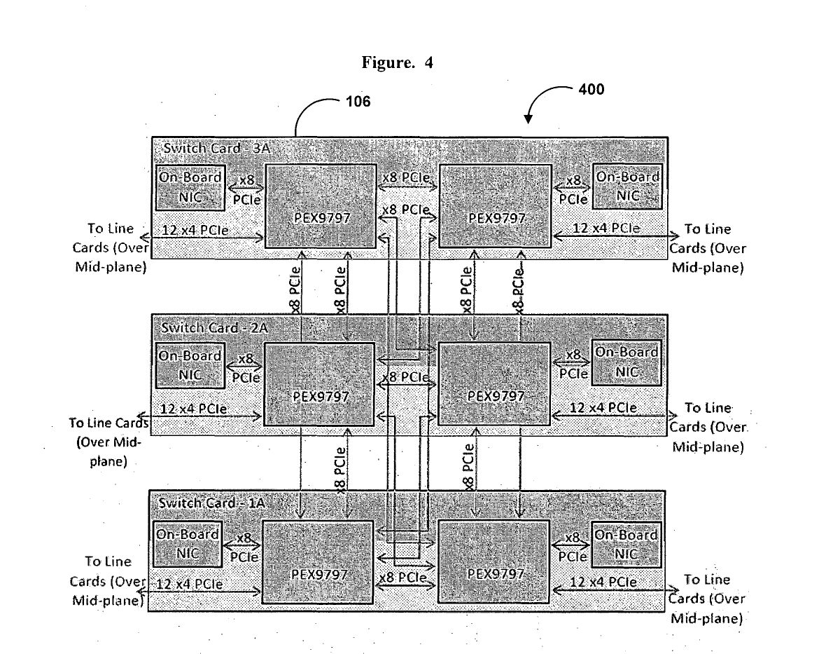

FIG. 3 is a schematic architecture illustrating connections of the different interfaces with each other, according to an embodiment of the present invention.

Further, according to the present invention, the approximate power consumption of the MDC is between 8000 W. The MDC system uses 7×1200 W power supply units to cater the power with N+1 redundancy. The power supply modules of the MDC can be, but not limited to, D1U54P-W-1200-12-HxxxC from Murata, PET1300-12-054NA from Power One, and the like.

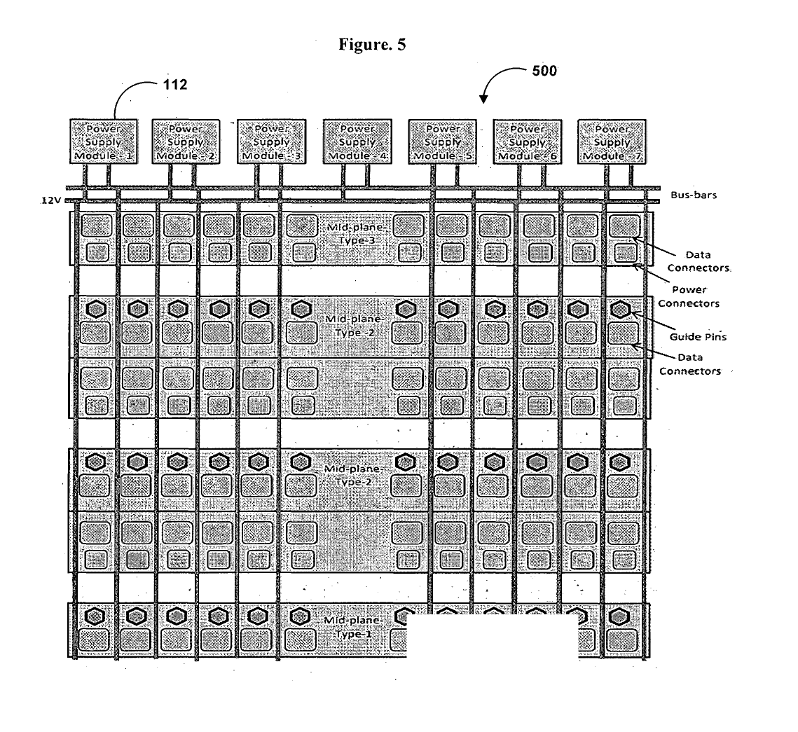

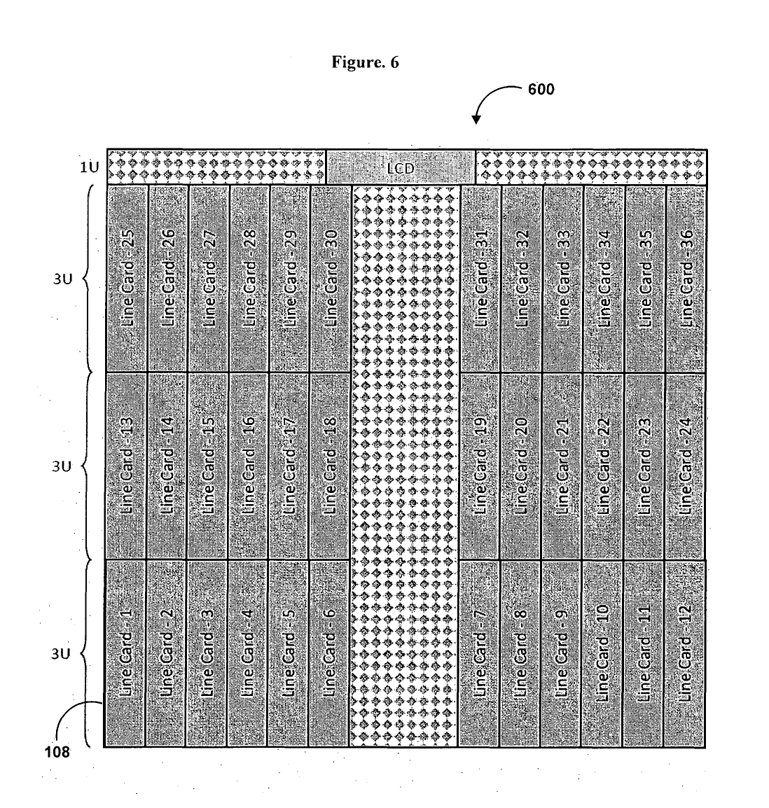

FIG. 4 is a schematic diagram illustrating providing power supply to the MDC, according to an embodiment of the present invention. According to the present invention, a power supply card is used to integrate the individual power supply units. FIG. 5 is a schematic diagram illustrating architecture of the backplane power supply of the MDC, according to an embodiment of the present invention.

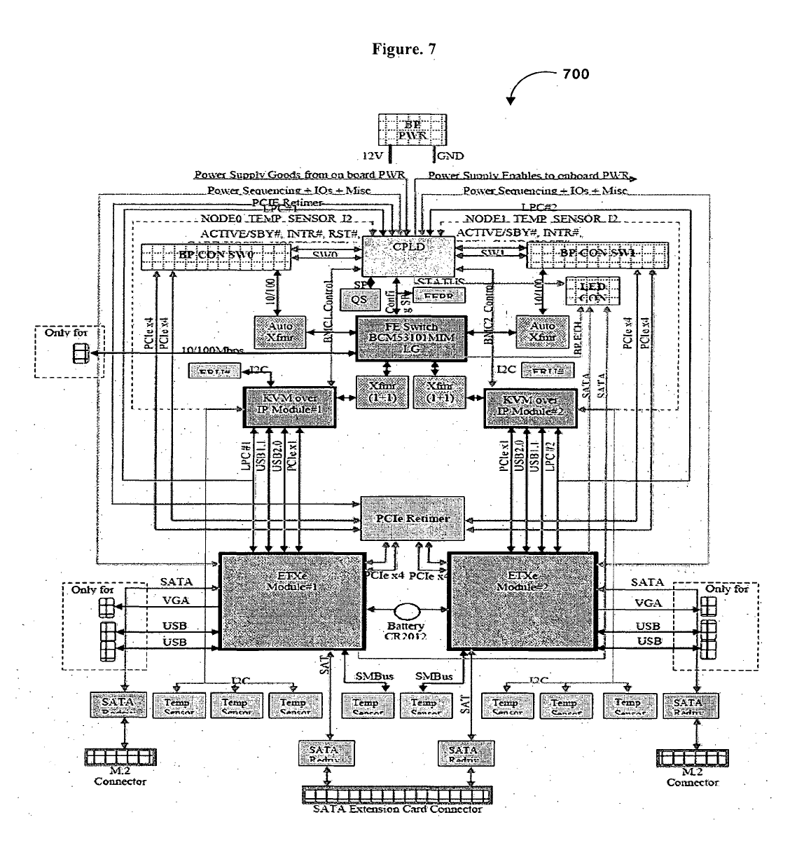

FIG. 6 is a schematic diagram illustrating server card placement of the MDC, according to an embodiment of the present invention. The MDC1000 can accommodate 36 server cards, wherein each server card has option to load maximum of two Intel Xeon-D processors. The server card has two x4 PCIe Gen3 lanes connected to one switch card over mid-plane. The MDC1000 switch card in aggregation mode support 64 Gbps connectivity from one XEON-D processor. One x4 PCIe Gen3 lane can be used for Ethernet NIC/data-path acceleration module and host to host connectivity and other x4 PCIe Gen3 lane can be used for storage bay connectivity. In an embodiment of the present invention, the server Card can use Intel Xeon-D 1540/1520 CPU processors. The server card can integrate all the core components and standard I/O interfaces. In an embodiment of the present invention, the MDC1000 server card can support the interfaces such as, but not limited to, PCI Express, LAN port of 10/100 Mbps speed capacity, USB ports, SATA ports, and the like. In another embodiment of the present invention, separate Keyboard, Video and Mouse (KVM) controller device scan be used for each processor node.

Further, the server card CPU supports 3×DDR4 small outline dual in-line memory (SODIM) sockets. The memory type supported can be DDR4 and maximum memory size supported by each CPU is 3×16 GB. The Server, card can use 3×16 GB DDR4 SODIM modules on each CPU (48 GB per CPU). Further, according to another embodiment of the present invention, SATA ports of the server card can be used as, but not limited to, one SATA port from first Xeon-D processor is used to provide support for a mSATA/M.2 disk, one SATA port from second Xeon-D is used to provide support for a mSATA/M.2 disk, one SATA port from first Xeon-D processor is used to provide support for a SATA HDD, one SATA port from second Xeon-D processor is used to provide support for a SATA HDD, and the like.

According to another embodiment of the present invention, AST2400, an Integrated Remote Management Processor (IRMP) can be used to provide the necessary KVM and Baseboard Management Controller (BMC) features on Server Card. According to another embodiment of the present invention, the server card comprises of an 5-port Ethernet switch, wherein the Ethernet switch provides two internal RMII interfaces and two external 10/100 TX/FX ports. The 10/100 TX/FX Ethernet ports are connected to the management Ethernet switches through the backplane.

According to another embodiment of the present invention, the server card backplane interfaces comprise of, but not limited to, four x4 PCIe Interface, two 10/100 TX/FX Ethernet Interface, two I2C Interface, 12V DCIN, and the like. Further, the server card supports debug connectors from each CPU module for bring-up testing, wherein the debug interfaces supported by the server card can include, but not limited to, 1×VGA interface, 2×USB2.0 interface, 1×LPC bus, 1×10/100 Ethernet interface, and the like. According to another embodiment of the present invention, 12V input voltage coming over the backplane can be used to power the Server Card. The on board voltages can be generated locally using DC-DC switching regulators and low dropout (LDOs) regulators. According to another embodiment of the present invention, power and reset sequencing can be implemented using a complex programmable logic device (CPLD) with necessary power monitoring circuits. A Power Button and Reset Button can be provided on board for testing.

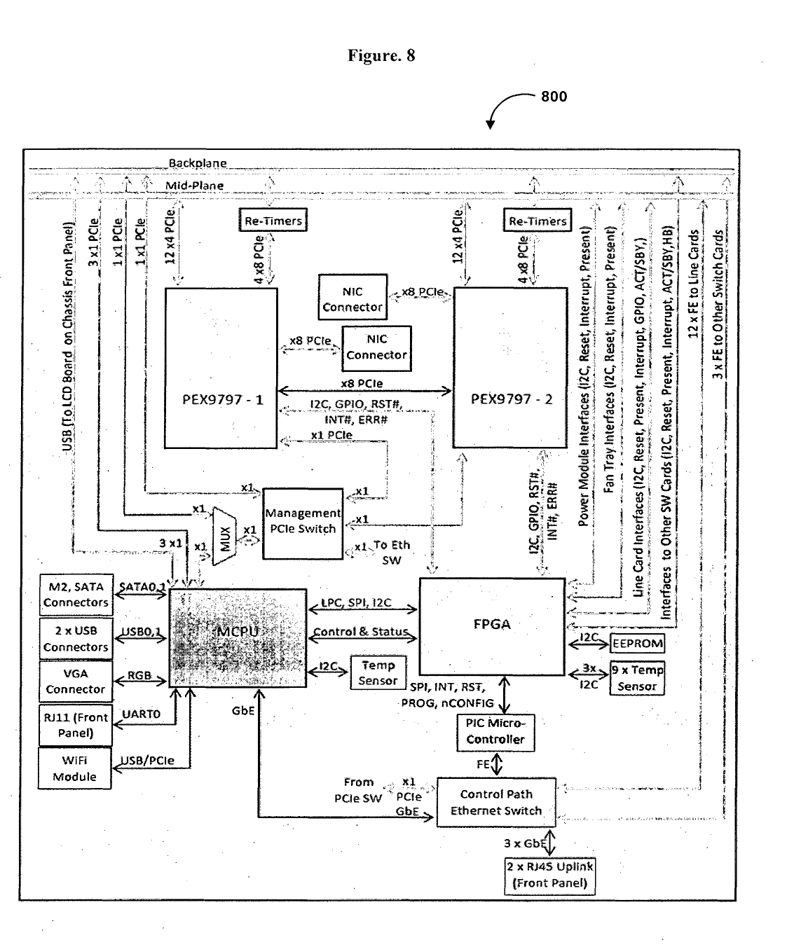

FIG. 7 is a schematic architecture illustrating switch card connection architecture with the other module in the MDC, according to an embodiment of the present invention. According to the FIG. 7, the MDC1000 has six switch cards, which can work in both redundant and aggregation mode. In redundant mode, there can be three active switch cards and three standby switch cards. A voting mechanism can be used between these cards to elect the active card. Redundancy management software running on MCPU of these cards can communicate between them over 1 Gbps Ethernet connection. During the system boot-up, if both the cards are present on the system, normally switch card with smaller slot number can act as active card and other card can become standby card. Switch cards can exchange the hardware version, software version, last boot details, system configuration files, and the like. One with approved higher version of the software has the eligibility to elect as active card. Standby card can sync the active card software over Ethernet connection. During the system operation, any configuration changes in the system can be synchronized in real time.

When active card fails, standby card can detect the failure using heart beat mechanism implemented in FPGA. When standby card FPGA detect the absence of heart beat from active card switch card, it interrupts MCPU of standby card. Standby card can check the status of active card over Ethernet link and if active card is not in operating condition, it can take over all functions of active card and act as active card and it can send fault alarm to administrator over management path. All Management function of endpoints (NIC) and hosts connected to system can be managed by new active card and all data path traffic can be re-routed through active switch card PCIe ports. To re-route the data traffic, new active card can make all link down indication to host processors and after re-assigning the new data path it can generate a link up indication to host processors. Redundancy management driver installed at the host makes a decision to re-route the PCIe packets to active PCIe interface from the host application software.

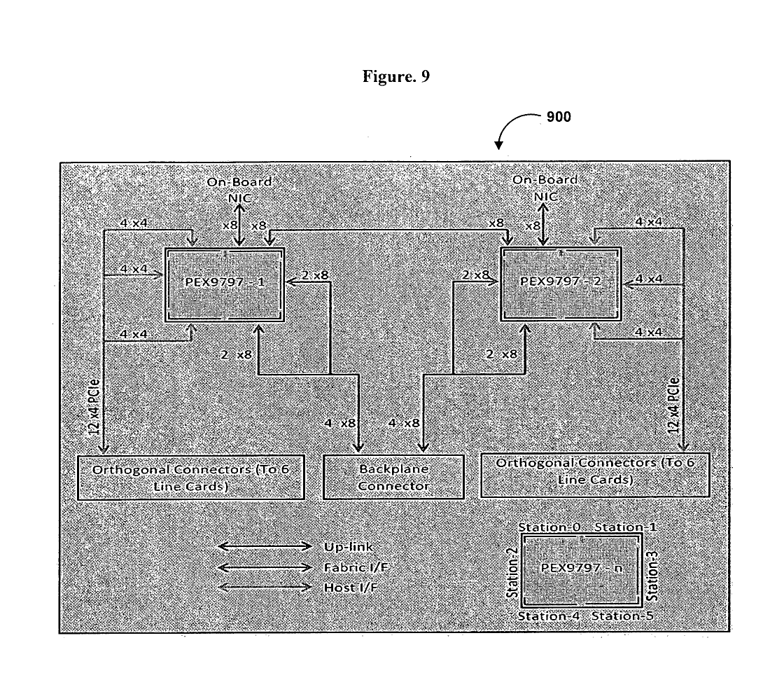

FIG. 8 is a schematic architecture illustrating MDC switch data path, according to an embodiment of the present invention.

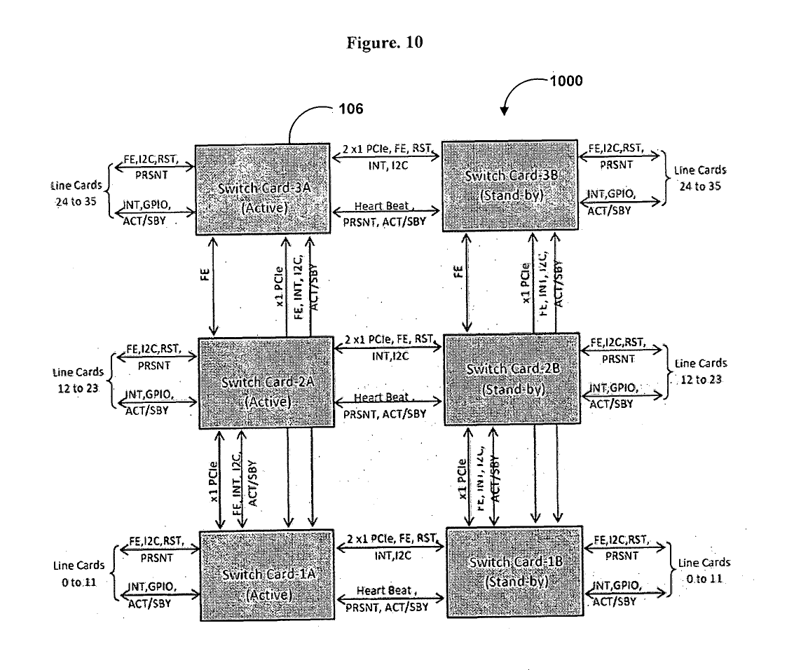

FIG. 9 is a schematic architecture illustrating MDC system control path, according to an embodiment of the present invention.

According to an embodiment of the present invention, the MDC1000 has an option to populate 36 storage cards and each storage card can house 6 HDD/SDD. Each storage blade can be populated in the place of server cards. Therefore, the MDC1000 can use as a converged solution of storage and server. In MDC1000 the disk bay can be shown as directly attached storage to each processor or VM and Management software can configure storage bay according to the system requirements. In another embodiment of the present invention, PIC32 from microchip can be used as BMC on the Storage Card. In another embodiment of the present invention, the storage card backplane can support one or more of, but not limited to, four x4 PCIe Interface, two 10/100 TX/FX Ethernet Interface, two I2C Interface, 12V DCIN, and the like.

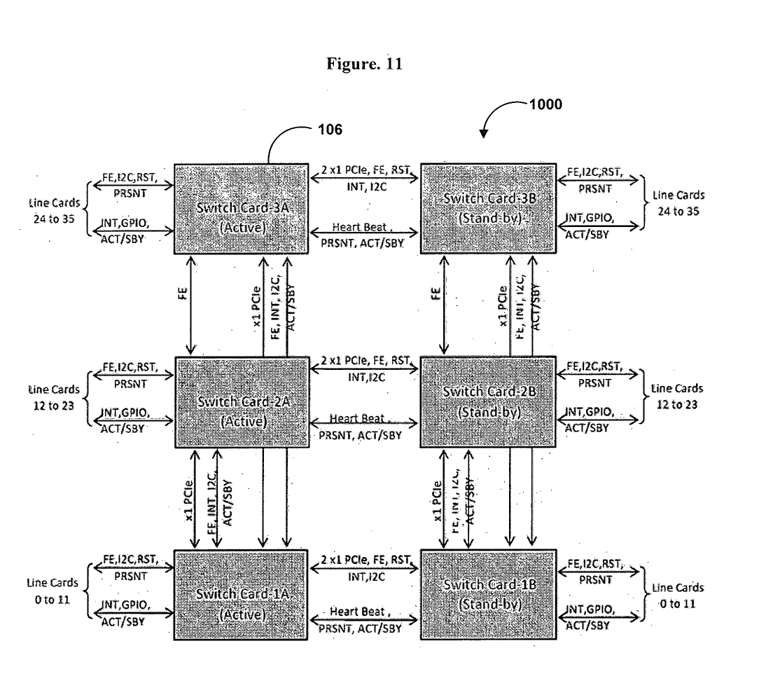

FIG. 10 is a schematic diagram illustrating structure of anexternal enclosure of the MDC, according to an embodiment of the present invention. The MDC1000 is a 10U system with 18″ width and 17.5″ height. It has a length of 36″ towards its back panel. All server and storage cards are hot swappable and can be removed from the front panel. There are eject button on the front panel of all the cards and once eject button is applied; a system management controller can do a graceful shutdown operation and allow user to remove the same from the system.

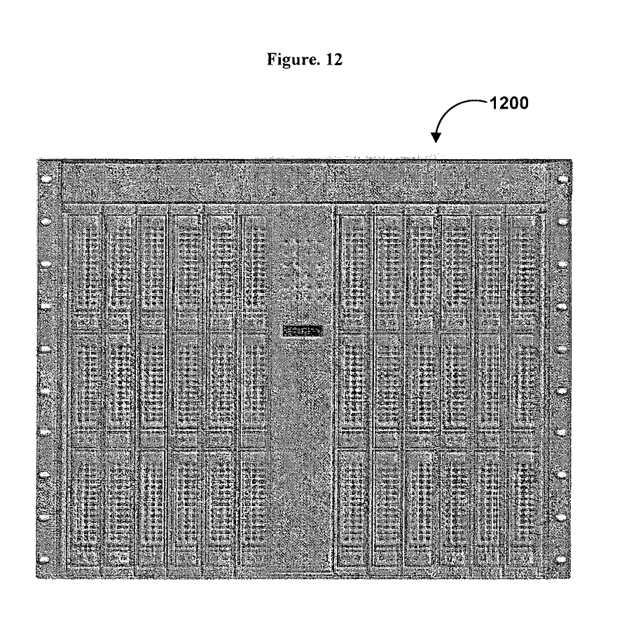

FIG. 11 is a mechanical diagram illustrating front panel of the MDC, according to an embodiment of the present invention. According to the FIG. 11, switch card can divide front panel into two halves, left side cards and right side cards. In each slot, orientations of slot guide pins are arranged such that cards cannot enter the chassis in wrong direction. There are indications on the front panel for card status, power on indication, and type of cards. For each cards, ejector mechanism is implemented to support hot swap functionality of the card.

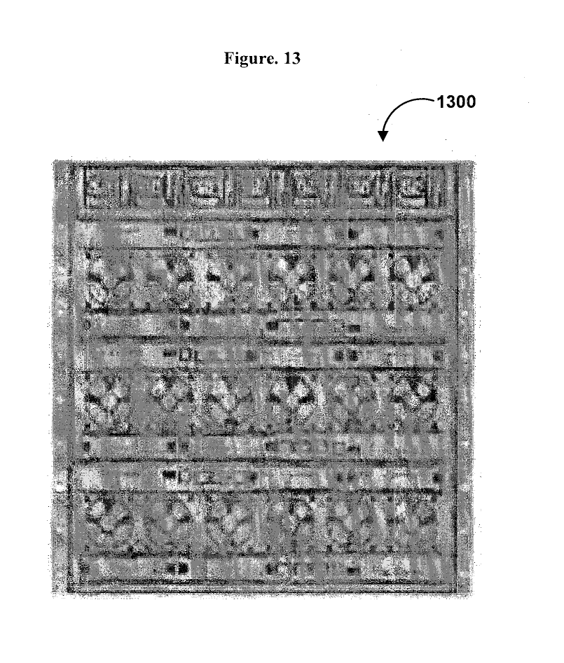

FIG. 12 is a mechanical diagram illustrating rear section of the MDC, according to an embodiment of the present invention. According to FIG. 12, all the interface connectors are terminated on rear panel of the system. There are options for seven power module sockets and management Ethernet connections. In between the FAN trays, there are twelve. NIC cards' SFP module provisions to connect to data center aggregation switch.

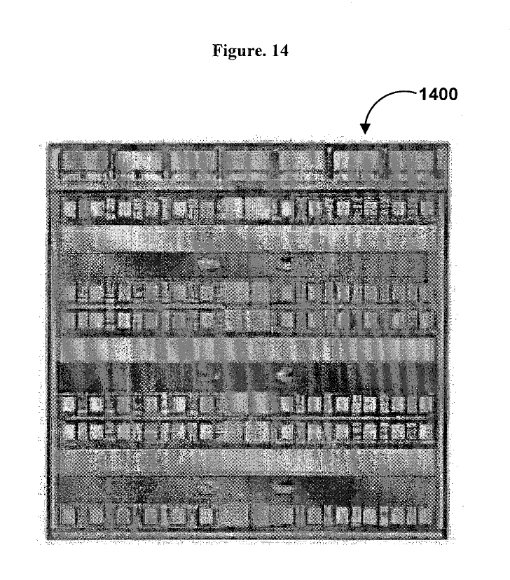

FIG. 13 is a mechanical diagram illustrating backplane of the MDC, according to an embodiment of the present invention. According to the FIG. 13, the backplane of the MDC comprises of plurality of power cross bars that are running over the mid plane to support 8 KW load of MDC1000. It is difficult to run 8 KW of power over PCB traces and so cross bar architecture is implemented in the system. The cross bar is an insulated copper plate which can carry high current required for the system, which is a propriety design as standard cross bar won't match MDC1000 requirements. According to the present invention, split mid plane is a unique concept which increases the heat flow within system, it increase the heat transfer area by 2.5 to 3 times compared other traditional designs.

According to another embodiment of the present invention, a micro data center (MDC) comprises of MDC management method can monitor and handles the working of the MDC, according to an embodiment of the present invention.

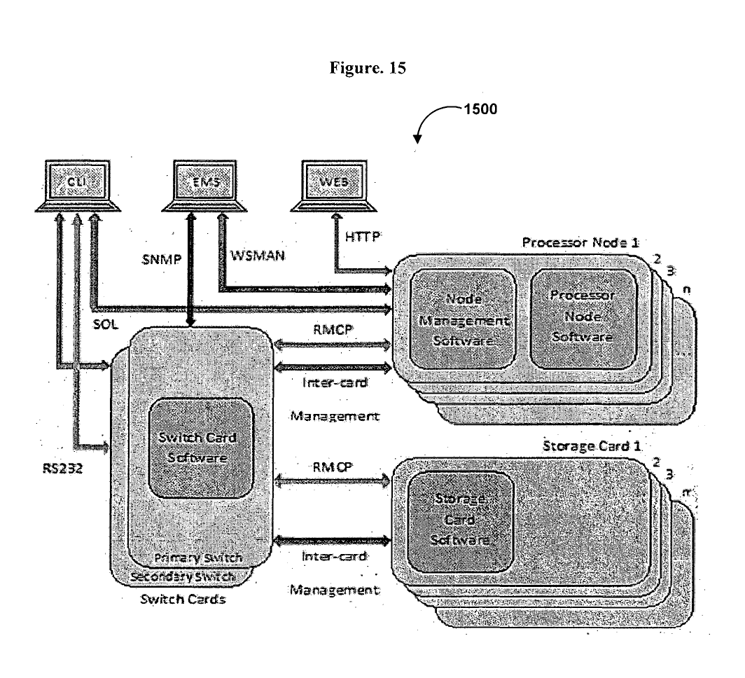

FIG. 14 is a block diagram of architecture illustrating MDC system, according to an embodiment of the present invention. The MDC system comprises of six switch cards, maximum of 36 server cards and 36 storage cards. The MDC can give the system level management of all switch cards, server cards and storage cards. The MDC has support of CLI and Web based management utility for managing system level management features. The MDC Management software server component running on MCPU of switch card uses RMCP protocol to communicate with IPMI 2.0 client nodes. Further, System management, configuration and monitoring can be done by switch card module.

In another embodiment of the present invention, the System configuration and monitoring are done through EMS (element management software), Command Line Interface (CLI) and Web. Through CLI, it is possible to access each processor node with SOL (serial over LAN), telnet and Secure Shell (SSH). The EMS is windows based software which uses Remote Management Control Protocol (RMCP), Web service Management (WSMAN) and Systems Management Architecture for Server Hardware (SMASH). Through EMS it is possible to monitor and configure the whole system. With web interface each processor node can be accessed. The MDC also having inter-card communication using the management LAN feature in the system.

According to an embodiment of the present invention, the CLI and web utility can be used for, but not limited to, viewing the MDC chassis, cards, processor node and switch details and health information, all event and Management logs down to the node level, active user sessions (both via CLI and web interface), and power, fan and temperature details, viewing the MDC firmware versions and updating firmware for components, including the chassis components, cards, processor nodes, and switches using local or remote files, or files that are loaded in the MDC firmware repository, managing the power and booting of all server nodes, and the power for cards and switches, configuring MDC chassis networking, IO Modules and acceleration modules, configuring MDC SSL certificate security, time settings, and user accounts, configuring MDC offload sessions and network bandwidth, configuring MDC stacking support, and the like.

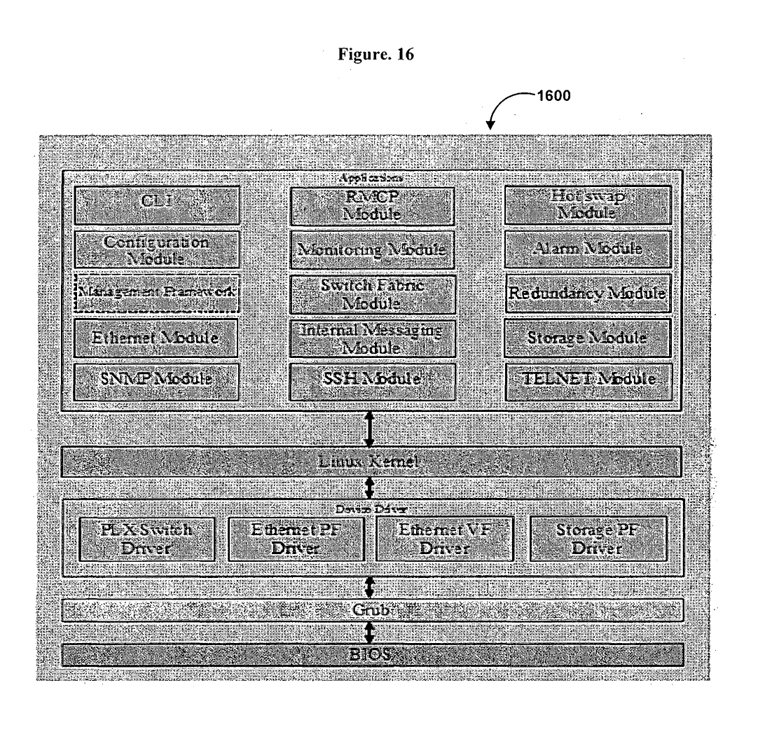

FIG. 15 is a block diagram of architecture illustrating switch card of the MDC management system, according to an embodiment of the present invention. The entire MDC management application can be running on the switch cards. The MDC system should have minimum of one Power Supply, switch card, IO card, and FAN controller and the like to boot up. Administrator of the system can configure each slots of MDC as server card slot or storage card slots based on the customer requirement. Even though the MDC has the capability to re-configure the slots based on user requirement on the fly (any card any slot), it is advisable to identify the approximate configuration during configuration cycle. Previously configured storage card slot can be used for storage only. If user wants to change a storage card slot into server card slots, a soft reconfiguration should be applied on MDC switch card by the MDC management application. Ideally, it can affect existing data path hardware and related applications of the server card which is being removed. The existing server card can be hot swapped out and the slot must be configured as storage slots before plugging the storage card.

The MDC has the support to provision the system and user can specify the type of storage, co-processor and server card in the system. System menu can list out different type of cards supported in the system. If a wrong card is plug in the system, then MDC power management system cannot switch on the payload power of the card, it throw up an LED error indication on the front panel of the card and also update alarm in the system monitor.

The X86 based processor can be used as control processor in switch card. Linux operating system can be customized for switch card processor. The switch card functionality can include, but not limited to, provide management interface like Simple Network Management Protocol (SNMP), SSH, TELNET and CLI, status monitoring, alarm handling, statistics collection, hot plug, redundancy handling, system configuration, and the like.

In an embodiment of the present invention, the switch card comprises of a Basic Input/Output System (BIOS), wherein the BIOS can be used as first stage boot loader in switch card. The BIOS can be customized for switch card. The BIOS can support PXE boot and can be supporting Systems Management Architecture for Server Hardware (UEFI) feature. The switch card further comprises of GR and Unified Boot loader (GRUB), wherein the GRUB can be used as second stage boot loader in switch card. The GRUB can also be supporting UEFI feature. The switch card software can further comprise of device drivers that can include a PEX Switch Driver, wherein PLX provided driver for PEX9797 would be ported for switch card to support multiple PEX9797 chipsets, an Ethernet PF Driver, wherein SRIOV based NIC cards would be used in switch card, which can be ported for switch card processor, an Ethernet VF driver, wherein SRIOV based NIC cards would be used in switch card and can be allocated to the switch card for in-band management, and can be ported for switch card processor, a storage PF driver, wherein SRIOV based storage controllers would be used in storage card, which can be ported for switch card processor.

In another embodiment of the present invention, the switch card further comprises of a plurality of application modules. In an embodiment of the present invention, the switch card comprises of a Remote Module Control Processor (RMCP) module, wherein the switch card interacts with the management application in server nodes and storage nodes in other cards via the RMCP module. Further, the switch card comprises of a Simple Network Management Protocol (SNMP) Module, wherein the EMS communicates with MDC via the SNMP module. The SNMP module implements SNMP agent functionality. The SNMP modules can also implement MIB for the system. Net-SNMP can be used to implement SNMP agent.

Further, the switch card comprises of a SSH Module that can implement SSH server functionality. A secure access to the system CLI can be provided via the SSH. Further, the switch card software comprises of a TELNET Module that can implement TELNET server functionality. A secure access to the system CLI can be provided via the TELNET. Further, the switch card software comprises of a command line interface (CLI) that can implement the command line interface to the user. Commands can be available for system configuration, statistics and status monitoring. Open source CLI framework can be used to implement the CLI. The switch card software can further comprises of a Configuration Module that can handle configuration requests from CLI and SNMP. The configuration module configures the system sub components over RMCP/Internal messaging.

The switch card further comprises of an internal messaging module that can implement the internal communication over management Ethernet. Custom protocol can be implemented for internal communication. The server nodes, storage cards and switch card can use this protocol for communication. Further, the switch card software comprise of an Ethernet Module that can handle the Ethernet virtual function assignments to multiple server nodes. The Ethernet Module can also handle dynamic VF assignment requests. The switch card software can further comprise of a Storage Module that can handle the storage controller virtual function assignments to multiple server nodes. The Storage module can also handle dynamic VF assignment requests.

The switch card further comprises of a monitoring module that periodically collects the status of the system via RMCP and internal messaging protocol, an alarm module that can handle the faults in the system. Alarm module generates the alarm to external management servers, a hot swap module that can handle the hot insertion and removal of Field Replaceable Units (FRU's) in the system, and can allocates/de allocates resources dynamically to the FRU. The switch card can further comprise of a management framework, wherein the Management framework from third party can be used to streamline management access different sources like CLI and EMS. The Management framework module provides API for reading/writing configuration items in the system. Simultaneous configuration of the same item from different management sources can be serialized in this module.

The switch card further comprise of a Redundancy Module that can implement the redundancy feature in the MDC system. The system supports switch card redundancy, Ethernet redundancy and storage redundancy. The Redundancy module periodically synchronizes the configuration and status information between switch cards. The redundancy can be either enabled or disabled. Further, the switch comprises of a Switch Fabric Module that can manage the PEX9797 fabric switch. The main features of the switch fabric module can include, but not limited to, PEX9797 initialization, runtime event handling, redundant switch configuration sync, and the like.

The embodiments herein and the various features and advantages details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein can be practiced and to further enable those of skill in the art to practice the embodiments herein. Accordingly, the examples should not be construed as limiting the scope of the embodiments herein.

We claim:

1. A Micro Data Center (MDC) system, comprising a rack mountable box (100) housing:
one or more uplink interfaces (102);
one or more management interfaces (104);
one or more switch cards (106);
one or more line cards (108);
one or more server cards (110);
a power supply module (112);
one or more visual indicators (114);
a storage tray (116); and
one or more Input-Output (I/O) cards (118);
wherein the MDC system is a reconfigurable data center in a box model, where the one or more components of the MDC system are interoperably connected through on a peripheral component interconnect express (PCIe) Express MDC Super compute Fabric.

2. The system of claim 1, wherein the one or more uplink interfaces (102) comprises of 12×8 PCIe uplink ports, support for custom or standard low profile half-length PCIe cards and support for at least one of 40G, 10G and Gigabit Ethernet (GbE) Network Interface Controllers (NICs).

3. The system of claim 1, wherein the one or more management interfaces on each switch card is of type 4×GbE electrical ports over RJ-45 connector.

4. The system of claim 1, wherein the power supply input to the MDC is in the range of 100V to 240 VAC current, where the MDC unitworks on 7×1200 W power supply module in 6+1 mode.

5. The system of claim 1, wherein the switch card comprises of 2×x4 PCIe interfaces to each server slot, 2×x8 PCIe to IO card, 2×PCIe reference clock to IO card, 1×FE interface to each Server slot, 1×FE interface to a second switch card, 2×FE uplink port to IO card, 6×I2C interface from a Master Control Processing Unit (MCPU) to Server slots for IP Multimedia Communication (IPMC) support, 1×Reset output to each Server slot; 1×output line per 12 Server slots to select the processor to be reset; 1×output lines per 12 Server slots to select board reset or processor reset, 1×Interrupt input lines per 12 Server slots; 1×card presence input line from each server slot, 2×card presence input lines from IO card, 2×GPIO signals to each Server slot, 1×input and 1×output heart beat signal to the second switch card, 7×geographical address input lines, 12V main power from the mid-plane to the switch card.

6. The system of claim 1, wherein the one or more switch cards is adapted to operate in redundant mode or in aggregate mode.

7. The system of claim 1, wherein the one or more visual indicators comprises of one tri color Light Emitting Diode (LED) on each switch card to indicate a power status, a KVM status, Ethernet link and activity status, and an LED panel containing one LED per slot to indicate a configuration status of the slot.

8. The system of claim 1, wherein the one or more server card comprises of 2×x4 PCIe interfaces to each switch card, 1×Fast Ethernet (FE) interface to each switch card, 2×Inter-Integrated Circuit (I²C) interface to each switch card, 1×reset input from each switch card, 1×input line from each switch card to select the processor to be reset, 1×input line from each switch card to select board reset or processor reset, 1×interrupt output to each switch card, 1×input line from each switch card to indicate each a switch card status, 1×output line to switch cards to indicate card presence status, 2×General Purpose Input/output (GPIO) signals to switch cards, 7×geographical address input lines and 12V main power from a backplane of the MDC to the server card.

9. The system of claim 1, wherein the storage tray comprises of 1×8 PCIe interfaces to each switch card, 1×FE interface to each switch card, 2×I²C interface to each switch card, 1×reset input from eachswitch card, 1×interrupt output to each switch cards, 2×input line from each switch card to indicate the witch card status, 1×output line to switch cards to indicate card presence status, 2×GPIO signals to each switch card, 7×geographical address input lines and 12V main power from the backplane of the MDC to the server card.

10. The system of claim 1, wherein the one or more IO card comprises of 2×x8 PCIe interfaces to switch card, One x8 PCIe from each PCIe slot in the IO card, 1×PCIe reference clock from switch card, One clock to each PCIe slot in the IO card, 1×I2C interface to switch card, One I2C to each PCIe slot in the IO card, 12V main power and 3.3V stand-by power from the switch card to the server card.

11. The system of claim 1, wherein the MDC system is adapted to implements an acceleration virtualization using the PCIe express supported MDC super compute fabric and built-in low latency high speed interconnects.

12. The system of claim 1, wherein the MDC super compute fabric comprises of share hardware acceleration modules, storage modules, Graphical Processing unit (GPU) modules, Field-programmable Gate Array (FPGA) modules and sever modules.

13. The system of claim 1, wherein a switching capacity of the switch card in a range of 1.6 Terabits to 9.6 Terabits.
